(19) United States
(12) Patent Application Publication
(10) Pub. No.: US 2025/0239481 A1
(43) Pub. Date: Jul. 24, 2025

(54) METHOD OF FABRICATING ELECTRONIC CHIPS

(71) Applicant: STMicroelectronics International N.V., Geneva (CH)

(72) Inventors: Gregoire DELACOURT, TOURS (FR); Ludovic FALLOURD, Louans (FR)

(21) Appl. No.: 19/018,688

(22) Filed: Jan. 13, 2025

(30) Foreign Application Priority Data
Jan. 19, 2024 (FR) FR2400541

(51) Int. Cl. H01L 21/762; H01L 21/78

(52) U.S. Cl. CPC H01L 21/76224; H01L 21/78

(57) ABSTRACT

A method of manufacturing an electronic chip is provided. An example method includes an electronic chip with passivated flanks from a semiconductor substrate having a first surface covered with connection terminals and inside of which are formed chips, and the method includes: depositing a protection layer onto the first surface of the substrate; forming trenches or cavities between the chips; depositing an insulating layer into the trenches or into the cavities by atomic layer deposition; and removing the protection layer.

### CROSS REFERENCE TO RELATED APPLICATIONS

This application claims the priority benefit of French patent application number 2400541, filed on Jan. 19, 2024, entitled “Procédé de fabrication de puces électroniques”, which is hereby incorporated by reference to the maximum extent allowable by law.

### TECHNICAL FIELD

The present disclosure concerns the field of CSP (‘Chip-Scale Package’) chips type. It more particularly concerns a bare dice or bare chip manufacturing method.

### BACKGROUND

Bare chips comprise a substrate, made of a semi-conductor material, inside of which electronic circuits have been manufactured. The substrate is covered with connection terminals to allow an assembly of the chip, for example, with a printed circuit board. During the chip assembly, the connection terminals are welded or soldered to metal tracks or elements of the printed circuit. However, on assembly, the solder may rise along the flanks of the chip. Now, since the sides of the chip are made of a semiconductor material, this may cause a loss of electric performance (short-circuit, leakage current . . . ). There thus exists a need to avoid such phenomena.

Such chips are particularly advantageous in many fields.

### BRIEF SUMMARY

There exists a need to at least partly improve certain aspects of known electronic chip manufacturing methods.

This object is achieved by a method of manufacturing an electronic chip with passivated flanks from a semiconductor substrate having a first surface covered with connection terminals and inside of which are formed chips, the method comprising the following steps:
depositing a protection layer onto the first surface of the substrate,
forming trenches or cavities between the chips,
depositing a ceramic insulating layer into the trenches or into the cavities by atomic layer deposition,
removing the protection layer.

According to an embodiment, trenches are formed, the trenches extending from the first surface of the substrate to a second surface of the substrate.

According to an embodiment, cavities are formed by partially cutting the substrate from the first surface.

According to an embodiment, the method comprises a step during which the substrate is thinned from a second surface of the substrate to reach cavities.

According to an embodiment, the insulating layer is made of alumina.

According to an embodiment, the protection layer is a water-soluble layer.

Method according to any of claims 1 to 5, wherein the protection layer (130) is an adhesive layer sensitive to ultraviolet radiation.

The protection layer may be a first adhesive layer whose adhesive properties may be reduced to have a lower final adhesion for peel off. In various embodiments, the protection layer may be ultraviolet tape.

According to an embodiment, before or after the deposition of the insulating layer, the method comprises a step during which the protection layer is submitted to an ultraviolet radiation to decrease its adhesion properties.

According to an embodiment, the step of removal of the protection layer is carried out by bonding an additional adhesive layer and by simultaneously removing the additional adhesive layer and the protection layer.

This object is achieved by an electronic chip with passivated flanks comprising a semiconductor substrate, having a first surface covered with connection terminals, a second surface and flanks, at least a portion of the flanks being formed of a ceramic insulating layer extending from the first surface of the substrate.

According to an embodiment, the insulating layer covers a portion of the first surface.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, FIG. 1C, FIG. 1D, FIG. 1E, and FIG. 1F show cross-section views illustrating steps of a method of manufacturing electronic chips with passivated flanks according to a specific embodiment;

FIG. 2A, FIG. 2B, FIG. 2C, FIG. 2D, FIG. 2E, FIG. 2F, and FIG. 2G show cross-section views illustrating steps of a method of manufacturing electronic chips with passivated flanks according to another specific embodiment;

FIG. 3A, FIG. 3B, FIG. 3C, FIG. 3D, FIG. 3E, and FIG. 3F show cross-section views illustrating steps of a method of manufacturing electronic chips with passivated flanks according to another specific embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

The method of manufacturing a bare die or bare chip with passivated flanks comprises at least the following steps:
a) providing a semiconductor substrate 110 having a first surface 111 covered with connection terminals 107 and inside of which are formed chips 100,
b) depositing a protection layer 130 onto the first surface 111 of substrate 110, to cover connection terminals 107,
c) forming trenches or cavities 120 between chips 100,
d) depositing a ceramic insulating layer 121 into the trenches or into cavities 120 by atomic layer deposition,
e) removing protection layer 130.

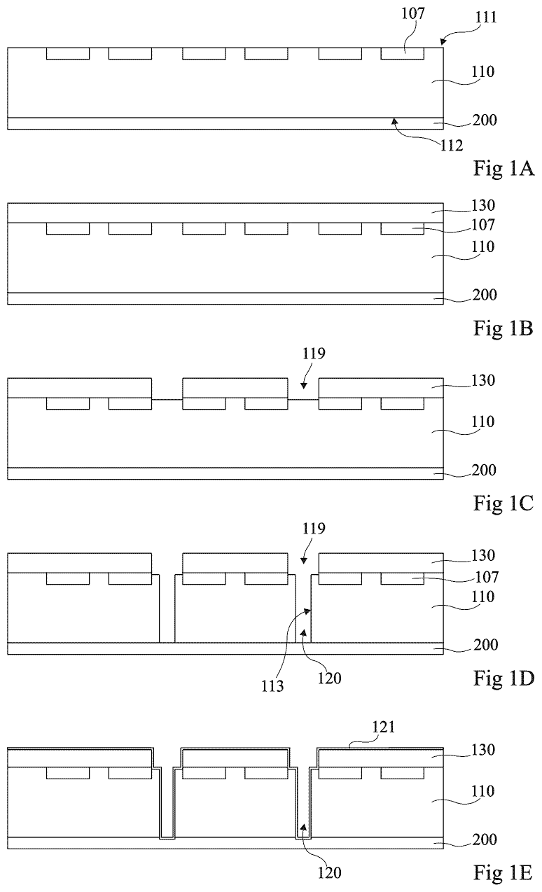

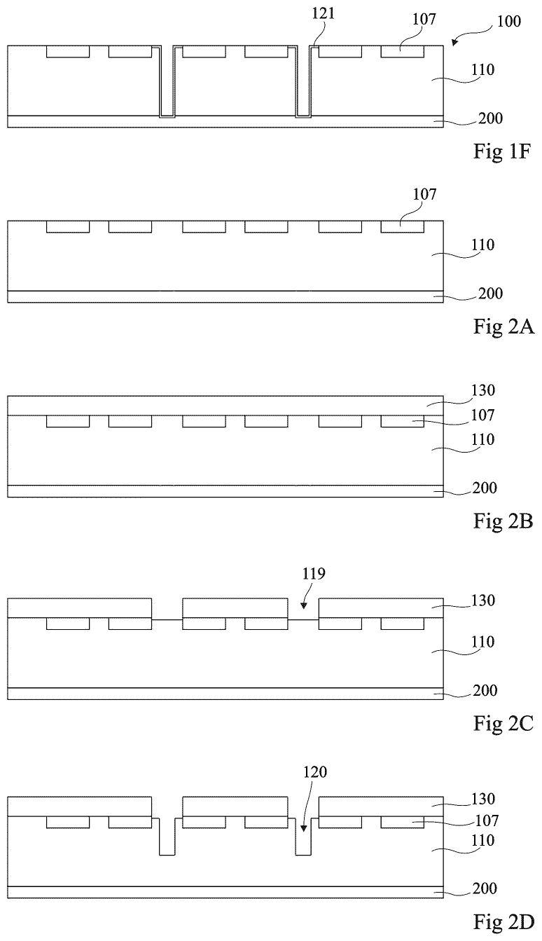

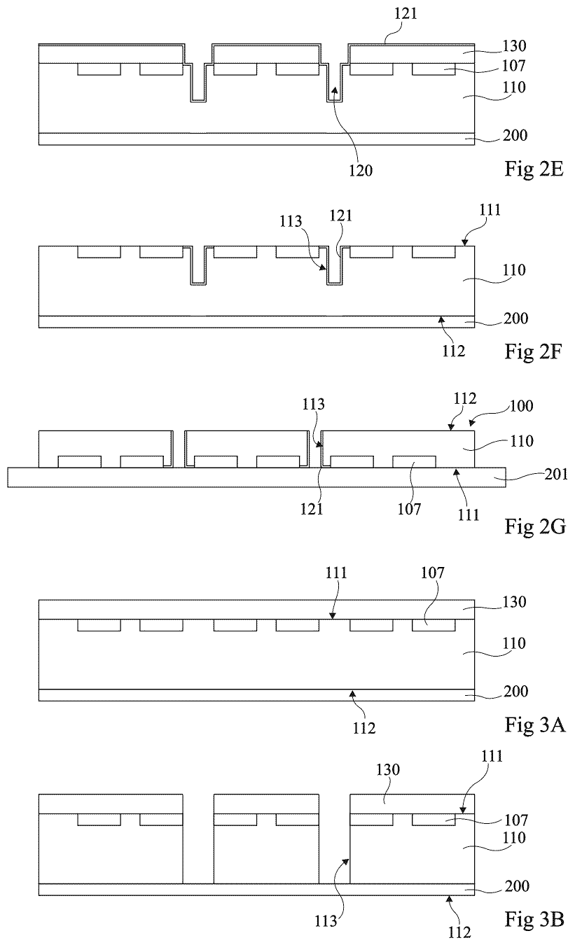

According to a first alternative embodiment, referring to FIGS. 1A to 1F and 2A to 2G, the method of manufacturing an electronic chip with passivated flanks comprises the following steps:
a) providing a semiconductor substrate 110 having a first surface 111 covered with connection terminals 107 and inside of which are formed chips 100 (FIGS. 1A, 2A),
b) depositing a protection layer 130 on the first surface 111 of substrate 110 (FIGS. 1B, 2B), protection layer 130 being soluble in an aqueous or organic solvent, preferably, in water,
   preferably, forming openings 119 in protection layer 130 (FIGS. 1C, 2C),
c) forming trenches or cavities 120 between chips 100, the width of trenches 120 being smaller than or equal to, preferably smaller than, the width of openings 119 (FIGS. 1D, 2D),
d) depositing a ceramic insulating layer 121 into the trenches or into the cavities 120 by atomic layer deposition (FIGS. 1E, 2E),
e) removing protection layer 130 by solubilizing it in the aqueous or organic solvent (FIGS. 1F, 2F),
   optionally, thinning substrate 110 on the back side (FIG. 2G).

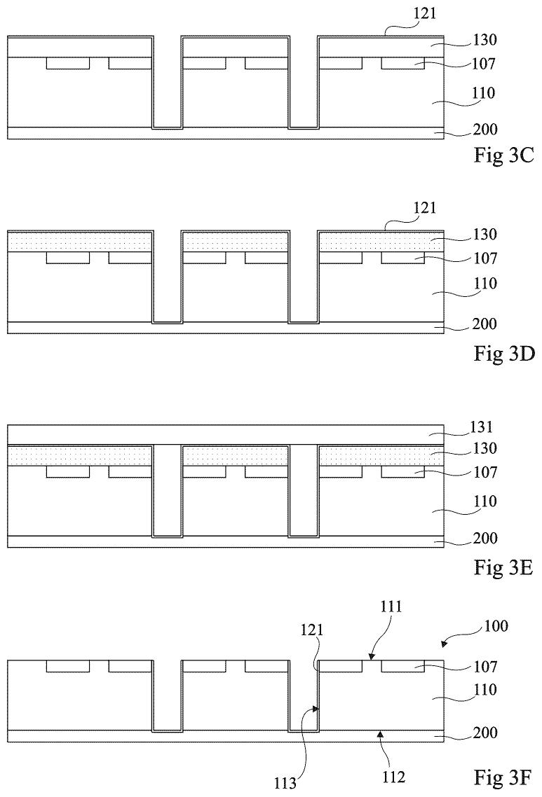

According to a second alternative embodiment, referring to FIGS. 3A to 3F, the method may comprise the following steps:
a) providing a semiconductor substrate 110 having a first surface 111 covered with connection terminals 107 and inside of which are formed chips 100,
b) depositing a protection layer 130 on the first surface 111 of substrate 110 (FIG. 3A), for example the adhesiveness of the protection layer being sensitive to ultraviolet radiation,
   optionally, forming openings 119 in protection layer 130,
c) forming trenches or cavities 120 between chips 100 (FIG. 3B),
d) depositing a ceramic insulating layer 121 into the trenches or into cavities 120 by atomic layer deposition (FIG. 3C),
   reducing the adhesives properties of the protection layer 130, for example by submitting the protection layer to an ultraviolet radiation to decrease its adhesive properties (FIG. 3D),
   optionally, thinning substrate 110 on the back side,
e) removing protection layer 130 (FIGS. 3E and 3F), by bonding an additional adhesive layer 131, and by simultaneously removing adhesive layer 130 and the additional adhesive layer (‘peeling’).

In various embodiments, the protection layer may be a first adhesive layer whose adhesive properties may be reduced to have a lower final adhesion for peel off. In various embodiments, the protection layer may be ultraviolet tape.

According to this second embodiment, the protective layer 130 has an adhesion that is both high enough to adhere when deposited and low enough, once its adhesive properties have been reduced, not to cause the components to move during removal. For example, the adhesive part of the protective layer is sensitive to ultraviolet radiation.

With such a method, the sides 113 of the chips 100 thus obtained are passivated by means of an insulating layer 121. A potential contamination (due to a defective assembly with the board) is thus avoided and there is no degradation of the electric performance.

At step a), the manufacturing of the discrete component(s) and/or integrated circuits has been completed. Chips 100 are formed in a same substrate 110, and to not have been singulated yet.

Substrate 110 comprises a first surface 111 (upper surface or front side) and a second surface 112 (lower surface or back side). The two surfaces 111 and 112 are parallel to each other. Surfaces 111 and 112 are connected together by lateral walls.

Substrate 110 is, for example, a semiconductor substrate, for example made of silicon. It may also be made of SiC.

Substrate 110 has, for example, a thickness in the range from 100 to 1200 μm, preferably from 300 to 900 μm, for example a thickness of approximately 725 μm.

One or a plurality of connection terminals 107 (also called electric contacts) are formed on the upper surface 111 of substrate 110 of electronic chip 100 and enable to connect it to other elements (chips or electronic devices). Preferably, at least two connection terminals 107 are formed on the upper surface 111 of substrate 110.

Electric connection terminals 107 are, for example, at a distance of from 10 to 30 μm from the lateral wall of the chip. Electric connection 107 may be positioned on the upper surface 111 of chip 100 or flush with upper surface 111 (that is, reach the level of the upper surface 111 of chip 100).

Electric connection terminals 107 are also called “UBM” (for “Under Bump Metallization”). Electric connection terminals 107 are made of a conductive material. Electric connection terminals 107 comprise, advantageously, at least one of the following elements: gold, titanium, nickel, copper, or tungsten. Preferably, they comprise gold.

Chip 100 may comprise a discrete component or a plurality of discrete components. The discrete component(s) are, for example, selected from among transistors, diodes, thyristors, triacs, filters, etc. Chip 100 may comprise one or a plurality of electronic circuits. Chip 100 enables to implement different electronic functions.

The substrate provided at step a) is positioned on a support 200. Support 200 is generally an adhesive tape.

During step b), a protection layer is formed on the first surface 111 of substrate 110. The protection layer covers connection terminals 107 and protects them during the deposition of insulating layer 121.

According to a first advantageous alternative embodiment, protection layer 130 is a layer soluble in a solvent. Preferably, it is water-soluble. For example, it is a polymer such as carboxymethyl cellulose. These may also include Vinyl acetate-ethylene copolymer (VAE), ethylene-vinyl acetate emulsion (EVA), polyvinyl alcohol (PVOH) and polyanionic cellulose (PAC). Products marketed under the reference TOK TLDP-300 or under the reference DaeCoat can also be chosen.

According to a second advantageous alternative embodiment, the protective layer 130 is an adhesive layer whose adhesive properties can be reduced when subjected to an external factor. For example, it may be sensitive to ultraviolet radiation. By sensitivity to ultraviolet radiation, there is meant that, when the layer is submitted to an ultraviolet radiation (typically between 280 and 400 nm), its adhesion properties strongly or even completely decrease. Layer 130 may then be easily removed by peeling.

Protection layer 130 may be totally adhesive. For example, it may be an acrylic adhesive on a polymer film made of polyethylene (PE), polyethylene terephthalate (PET), polyvinyl chloride (PVC) or polyolefin (PO), in particular polyethylene (PE) or polypropylene (PP).

Alternatively, it may comprise a first adhesive portion sensitive to UV radiation and a second portion, non-adhesive and/or non-sensitive to UV radiation. The first portion is in contact with substrate 110. For example, it may be a thin adhesive layer and a non-adhesive base, for example made of polyolefin.

The protection layer 130 sensitive to ultraviolet radiation may be exposed to the radiation before or after the deposition of insulating layer 121.

After step b), the method may comprise a step during which openings 119 are formed in protection layer 130. According to the nature of the protection layer, the openings may be formed by mechanical action (saw, in particular) or by laser. For a protection layer 130 soluble in a solvent, a dry process, such as a laser process, will be privileged.

During step c), cavities or trenches 120 are formed in substrate 110.

Cavities or trenches 120 define the lateral contours of chips 100. More particularly, cavities or trenches 120 extend from the upper surface 111 of substrate 110. The trenches or cavities 120 have a depth and width specified to ensure precise separation of the chips, for example during trench formation or during the thinning step of substrate 110.

According to a first alternative embodiment, for example shown in FIGS. 1D and 3B, the trenches thoroughly cross substrate 110, that is, substrate 110 is cut from the first surface 111 to the second surface 112.

The thickness of trenches 120 is, for example, in the range from 10 to 80 μm.

According to a second alternative embodiment, for example shown in FIG. 2D, cavities 120 have a depth smaller than the thickness of substrate 110.

The depth of cavities 120 is, for example, in the range from 10 to 300 μm, preferably from 20 to 250 μm.

The thickness of cavities 120 is, for example, in the range from 10 to 80 μm.

The bottom of the cavities may be flat or concave.

This step c) is carried out by means of a cutting device. The cutting device is, for example, a mechanical etching tool such as a saw, or a laser etching tool. According to a preferred embodiment, the cutting device is a laser, preferably, the dice are singulated by laser (laser dicing or stealth dicing).

Preferably, for a water-soluble protection layer 130, the cutting is a laser cutting. For an adhesive protection layer 130, the cutting may be a mechanical cutting.

When openings 119 have been previously formed in protection layer 130, trenches or cavities 120 have a width smaller than or equal than the width of openings 119. Preferably, trenches or cavities 120 have a width smaller than the width of openings 119.

Openings 119 and trenches/cavities 120 may be formed in a same step, their widths are then identical.

During step d), an insulating layer 121 is deposited. The deposition is performed on the front side 111 of substrate 110. The deposition is a full-wafer deposition. Insulating layer 121 is deposited into cavities 120, on protection layer 130, and if relevant on the first surface of substrate 111 at the level of openings 119.

The insulating layer 121 is deposited by Atomic Layer Deposition (ALD). The deposition is a conformal deposition, even for high-relief topographies.

Insulating layer 121 is made of ceramic.

The insulating layer 121 can be a nitride or an oxide. It could also be boride or carbide. Preferably, insulating layer 121 is alumina. It can also be TiO2 or Y2O3.

During step e), the protection layer is removed. The removal of protection layer 130 enables to simultaneously remove the portion of insulating layer 121 which has been deposited above.

When protection layer 130 is a layer soluble in a solvent, it is placed into contact with this solvent, for example by immersion or preferably by high-pressure cleaning, to be removed. The solvent can be an organic solvent or an aqueous solvent. Preferably, the solvent is water.

When protection layer 130 is an adhesive layer, it is removed according to the following sub-steps:
bonding an additional adhesive layer 131 above protection layer 130, and in particular on the portion of insulating layer 121 which has been deposited on protection layer 130 (FIG. 3E), then
removing additional adhesive layer 131 (FIG. 3F).

Since additional adhesive layer 131 adheres to the protection layer via insulating layer 121, when it is removed, this enables to simultaneously remove protection layer 130.

The adhesion properties will be selected so that, when step e) is carried out, one removes the stack comprising the following successive layers: protection layer 130, the portion of insulating layer 121 positioned on protection layer 130, additional adhesive layer 131.

The method may also comprise a step of back side thinning (FIG. 2G). This step is, preferably, carried out before step e). It can be also carried out after step e). For this purpose, the structure is flipped and bonded by its front side 111 to a support 201. Support 201 is, for example, an adhesive tape band. The structure is, then, thinned from its back side 112 so that its substrate 110 has its final thickness. When cavities are formed at step c), the thinning step is, preferably, carried out so as to thin substrate 110 all the way to cavities 120 to separate the substrates of chips 100.

At the end of the method, the obtained chips 100 comprise passivated flanks 113. The passivation is due to the presence of the ceramic insulating layer 121. When units are assembled on PCB, the soldering materials do not wet insulating layer 121.

According to an advantageous variant, only a portion of side 113 may be passivated. The sides comprise a first portion formed in substrate 110, made of a semiconductor material, and a second portion made of an insulator 121. The passivated part of the flank is that which is closest to the active zone (i.e. close to the UBMs).

According to another advantageous variant, the entire side 113 is passivated.

When openings 119 have been formed in protection layer 130, the first surface 111 of substrate 110 is also locally covered with insulating layer 121, insulating layer 121 then covers (partially or totally) sides 113 and continues on the first surface 111 of substrate 110.

The chips can be bumpless CSP chips with a simple, solderable, electrically conductive metal contact zone (UBM, metal pad, etc.) or bumped CSP chips with additional connections raised from the chip itself (bump, pillar, etc.).

Chips 100 may then be bonded to an external device, for example, a printed circuit board or another component, by their upper surface 111.

For this purpose, a solder material is positioned between chip 103 and the external device. During the soldering, even if the solder material rises along the sides of the chips, they will operate properly.

Such CSP-type electronic chips have applications in many industrial fields, and in particular, in the field of telephony, in the automobile field, or the medical field.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an electronic chip with passivated flanks from a semiconductor substrate having a first surface covered with connection terminals and inside of which are formed chips, the method comprising:
depositing a protection layer onto the first surface of the substrate, wherein the protection layer is a water-soluble layer or an adhesive layer sensitive to ultraviolet radiation;
forming trenches or cavities between the chips;
depositing a ceramic insulating layer into the trenches or into the cavities by atomic layer deposition, wherein the ceramic insulating layer is made of alumina; and
removing the protection layer.

2. The method of claim 1, wherein trenches are formed, the trenches extending from the first surface of the substrate to a second surface of the substrate.

3. The method of claim 1, wherein cavities are formed by partially cutting the substrate from the first surface.

4. The method of claim 3, wherein the method comprises a step during which the substrate is thinned from a second surface of the substrate to reach the cavities.

5. The method of claim 1, wherein the insulating layer is made of alumina.

6. The method of claim 1, wherein the protection layer is a water-soluble layer.

7. The method of claim 1, wherein the protection layer is an adhesive layer sensitive to ultraviolet radiation.

8. The method of claim 7, wherein, before or after the deposition of the insulating layer, the method further comprises submitting the protection layer to an ultraviolet radiation to decrease its adhesion properties.

9. The method of claim 7, wherein removing the protection layer is by bonding an additional adhesive layer and by simultaneously removing the additional adhesive layer and the protection layer.

10. An electronic chip with passivated flanks comprising a semiconductor substrate having a first surface covered with connection terminals, a second surface, and a plurality of flanks, wherein at least a portion of the plurality of flanks are formed of a ceramic insulating layer extending from the first surface of the substrate.

11. The electronic chip of claim 10, wherein the insulating layer covers a portion of the first surface.

12. The electronic chip of claim 10, wherein the trenches or cavities have a depth and width specified to ensure precise separation of the chips.

13. A method of manufacturing an electronic chip with passivated flanks from a semiconductor substrate having a first surface covered with connection terminals and inside of which are formed chips, the method comprising:
depositing a protection layer onto the first surface of the substrate, wherein the protection layer is an adhesive layer whose adhesive properties can be reduced to have a lower final adhesion for peel off;
forming trenches or cavities between the chips;
depositing a ceramic insulating layer into the trenches or into the cavities by atomic layer deposition, wherein the ceramic insulating layer is made of alumina; and
removing the protection layer.

14. The method of claim 13, wherein the adhesive layer is comprised of an adhesive sensitive to ultraviolet radiation.
